(19) United States
(12) Patent Application Publication
(10) Pub. No.: US 2025/0183075 A1
(43) Pub. Date: Jun. 5, 2025

(54) SUBSTRATE MONITORING METHOD AND SUBSTRATE PROCESSING APPARATUS

(71) Applicant: TES CO., LTD, Yongin-si (KR)

(72) Inventors: Hong-Jun SHON, Yongin-si (KR); Jae-Jin LEE, Yongin-si (KR)

(73) Assignee: TES CO., LTD, Yongin-si (KR)

(21) Appl. No.: 18/966,024

(22) Filed: Dec. 2, 2024

(30) Foreign Application Priority Data
Dec. 4, 2023 (KR) 10-2023-0173563

(51) Int. Cl. H01L 21/67

(52) U.S. Cl. CPC H01L 21/67288

(57) ABSTRACT

The present disclosure relates to a substrate monitoring method and a substrate processing apparatus, and more particularly, to a substrate monitoring method and a substrate processing apparatus for detecting a warpage degree of a substrate by measuring a capacitance between an upper electrode and the substrate in a chamber when various processes are performed on the substrate.

### CROSS-REFERENCE TO RELATED APPLICATION

This application is based on and claims priority under 35 U.S.C. § 119 to Korean Patent Application No. 10-2023-0173563, filed on Dec. 4, 2023, in the Korean Intellectual Property Office, the disclosure of which is incorporated by reference herein in its entirety.

### TECHNICAL FIELD

The present disclosure relates to a substrate processing apparatus and a substrate processing method, and more particularly, to a substrate processing apparatus and a substrate processing method for easily cleaning an unnecessary thin film deposited on a backside and edge area of a substrate without inverting the substrate.

### BACKGROUND

Typically, a substrate processing apparatus performs various processes on a substrate inside a chamber, such as deposition, etching, and cleaning.

Inside the chamber, a process environment is created depending on temperature and pressure conditions, but conventionally, it is not easy to monitor a situation inside the chamber. For example, when a process is performed on a substrate, it is not easy to determine whether bowing, warpage, or bending occurs in the substrate.

In particular, recently, a substrate processing apparatus that deposits a thin film with a certain thickness on a backside of a substrate has been developed. However, when a thin film is deposited on the backside of the substrate by using the substrate processing apparatus, it is not easy to determine whether the substrate warps.

A technology of some conventional apparatuses has been disclosed for measuring the flatness of a substrate by measuring the current and voltage of a pair of electrodes located inside a chamber to measure impedance. However, these conventional apparatuses directly measure the voltage and current to calculate impedance, and thus have a difficult to accurately determine a warpage degree of the substrate due to a change in voltage and current.

### SUMMARY

The present disclosure is to provide a substrate monitoring method and a substrate processing apparatus, for detecting a warpage degree of a substrate by measuring a capacitance between an upper electrode and the substrate in equipment for depositing a thin film on a backside of the substrate.

The present disclosure is to provide a substrate monitoring method and a substrate processing apparatus, for increasing the accuracy of measurement of a capacitance between a pair of electrodes inside a chamber.

The present disclosure is to provide a substrate processing apparatus including a chamber providing a processing space for a substrate, an upper electrode disposed at an upper portion inside the chamber, a substrate support supporting the substrate inside the chamber, a lower showerhead disposed inside the substrate support and providing process gas or plasma toward a backside of the substrate, and a detector configured to measure a capacitance between the upper electrode and the substrate to detect a warpage degree of the substrate.

The upper electrode may include a plurality of split electrodes, and the detector may be configured to measure a capacitance between the plurality of split electrodes and the substrate.

When an amount of change in the measured capacitance is greater than or equal to a difference between an initial measured value and a predetermined threshold value, a process for the substrate may be terminated or the warpage degree of the substrate may be notified through an alarm.

When an amount of change in the measured capacitance is greater than or equal to a difference between an initial measured value and a predetermined threshold value, the warpage degree of the substrate may be displayed through a display unit.

A number or arrangement of the plurality of split electrodes may be changed to adjust an area in which a capacitance is measured by the detector.

When the detector includes a plurality of detectors, measured values of capacitances measured by the respective detectors may be compared with each other to compare warpage degrees depending on an area of the substrate.

The present disclosure is to provide a substrate monitoring method of a substrate processing apparatus including an upper electrode disposed inside a chamber, a lower showerhead supplying process gas or plasma toward a backside of the substrate, and a detector measuring a capacitance between the upper electrode and the substrate, the substrate monitoring method including measuring a capacitance between the upper electrode and the substrate by the detector, and determining a warpage degree of the substrate according to a measured value of the capacitance measured by the detector.

When the upper electrode includes a plurality of split electrodes, the detector may be configured to measure a capacitance between the plurality of split electrodes and the substrate.

The method may further include, when the detector includes a plurality of detectors, comparing measured values of capacitances measured by the respective detectors with each other to compare warpage degrees depending on an area of the substrate.

When an amount of change in the measured capacitance is greater than or equal to a difference between an initial measured value and a predetermined threshold value, a process for the substrate may be terminated or the warpage degree of the substrate may be notified through an alarm.

When an amount of change in the measured capacitance is greater than or equal to a difference between an initial measured value and a predetermined threshold value, the warpage degree of the substrate may be displayed through a display unit.

### BRIEF DESCRIPTION OF THE DRAWINGS

Embodiments will be more clearly understood from the following detailed description taken in conjunction with the accompanying drawings in which:

FIG. 1 is a side cross-sectional view of a substrate processing apparatus according to an embodiment of the present disclosure;

FIGS. 2A to 3B are plan views showing a structure of an upper electrode according to various embodiments; and

FIGS. 4A to 5B are graphs showing a change in a capacitance during a process for a substrate and show warpage of the substrate.

### DETAILED DESCRIPTION OF THE EMBODIMENTS

Hereinafter, the structure of a substrate processing apparatus 1000 according to an embodiment of the present disclosure will be examined in detail with reference to the drawings.

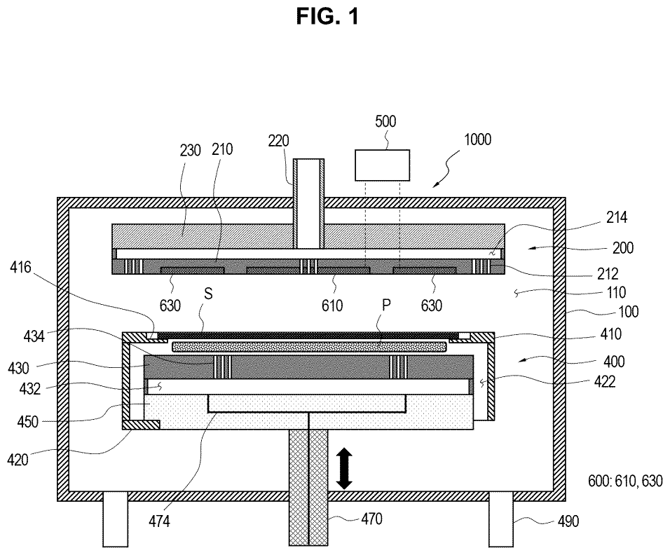

FIG. 1 is a side cross-sectional view of the substrate processing apparatus 1000 according to an embodiment of the present disclosure.

Referring to FIG. 1, the substrate processing apparatus 1000 may include a chamber 100 that provides a processing space 110 for a substrate S, an upper electrode 600 located at an upper portion inside the chamber 100, a substrate support 400 that supports the substrate S inside the chamber 100, a lower showerhead 430 that is located inside the substrate support 400 and provides a process gas toward a backside of the substrate S, and a detector 500 that detects a warpage degree of the substrate S by measuring a capacitance between the upper electrode 600 and the substrate S.

In detail, the chamber 100 may provide an accommodation space 110 therein in which various components required for a deposition process on a substrate are accommodated.

One side of the chamber 100 may be provided with an opening (not shown) through which the substrate is loaded into or unloaded from the accommodation space 110, and the opening described above may be provided with a door (not shown).

An upper heater 200 that supplies a purge gas, such as an inert gas, toward the upper surface of the substrate S may be provided at the upper portion of the chamber 100.

An upper supply path 220 through which purge gas is supplied may be connected to the upper portion of the chamber 100. The purge gas supplied along the upper supply path 220 is supplied to a lower portion through the upper heater 200.

The purge gas supplied from the upper heater 200 is supplied toward the accommodation space 110 at the lower portion, thereby preventing process gas supplied from the lower showerhead 430 from flowing into the upper heater 200.

In detail, the upper heater 200 may include a heater plate 230 and a showerhead plate 210 provided below the heater plate 230. A first buffer space 214 is provided between the heater plate 230 and the showerhead plate 210.

The heater plate 230 may include a heater (not shown) therein to heat the substrate S and the accommodation space 110 to a predetermined process temperature.

A plurality of first supply holes 212 may be formed in the showerhead plate 210.

Accordingly, the purge gas supplied through the upper supply path 220 is diffused in the first buffer space 214 and supplied downward through the first supply holes 212 of the showerhead plate 210. In FIG. 1, for convenience of illustration, the first supply holes 212 are illustrated as being formed only in a portion of the showerhead plate 210, but the first supply holes 212 may be formed over the entire surface of the showerhead plate 210.

A radio frequency (RF) power supply (not shown) that applies RF power to at least one of the upper heater 200 and the lower showerhead 430 may be further provided.

For example, the upper heater 200 may be connected to the RF power supply (not shown) to receive RF power. In this case, the lower showerhead 430 may be grounded and may function as a lower electrode.

When RF power is applied to the upper heater 200 during a process for the substrate S, the upper heater 200 may be capacitively coupled with the lower showerhead 430, and plasma P may be generated between the substrate S and the lower showerhead 430, and thus a thin film may be easily deposited on the backside of the substrate S.

The substrate support 400 may be provided to be moveable up and down at a lower portion of the accommodation space 110 and may support an edge of the backside of the substrate S. The lower showerhead 430 described above is provided inside the substrate support 400 and supplies process gas.

The substrate support 400 may be connected to a driving bar 470 that extends downward, and the driving bar 470 may be connected to a driver (not shown) such as a motor, and accordingly, the driving bar 470, the substrate support 400, and the lower showerhead 430 may move up and down by driving of the driver.

The substrate support 400 may include a substrate holder 410 that supports the edge of the backside of the substrate, and the lower showerhead 430 described above may be provided inside the substrate holder 410. The substrate support 400 may further include a lower plate 450 in which a heat exchange path (not shown) is formed.

In this case, the substrate holder 410 may be supported by a fixing portion 420 with a lower end connected to the lower plate 450.

The substrate holder 410 may extend upward from the fixing portion 420 and have a shape in which an upper end of the substrate holder 410 is bent toward the inside.

In this case, a concave portion 416 may be formed at the upper end of the substrate holder 410. Therefore, when the substrate is placed in the substrate holder 410, the substrate is inserted into the concave portion 416 to support the backside of the edge of the substrate.

Process gas may be supplied to the lower showerhead 430 through a lower supply passage 474 passing through the driving bar 470.

A second buffer space 432 may be provided in the lower showerhead 430, and the second buffer space 432 may be provided between the lower showerhead 430 and the lower plate 450. Alternatively, although not shown in the drawing, the second buffer space may be provided inside the lower showerhead 430. Although not shown in the drawing, a baffle or blocking plate for dispersing gas may be inserted between the lower showerhead 430 and the lower plate 450 or in the second buffer space 432.

A heat exchange path (not shown) may be formed in the lower plate 450, and a heat exchange fluid or the like may flow along the heat exchange path to adjust the temperature of the process gas or the inside of the chamber 100 through heat exchange.

The lower plate 450 may support the lower showerhead 430 and the substrate holder 410. In this case, the lower showerhead 430 may be connected to the upper surface of the lower plate 450. The fixing portion 420 supporting the lower end of the substrate holder 410 may be connected to the lower plate 450.

In this case, the fixing portion 420 may be provided in plural and the plurality of fixing portions 420 may be spaced apart at a predetermined interval along an outer circumference of the lower plate 450. That is, when the plurality of fixing portions 420 are provided, a space between adjacent fixing portions 420 may be opened downward and may communicate with the inside of the chamber 100. Accordingly, the space formed by a lateral surface of the lower showerhead 430, a lateral surface of the lower plate 450, and an inner surface of the substrate holder 410 may define an exhaust path 422.

In this case, some of the process gas supplied from the lower showerhead 430 is discharged to the lower portion of the chamber 100 through the exhaust path 422 and exhausted to the outside of the chamber 100 through an exhaust portion 490 provided at the lower portion of the chamber 100.

The purge gas supplied downward from the upper heater 200 may flow to the lower portion of the chamber 100 and may be discharged to the outside of the chamber 100 through the exhaust portion 490.

The upper electrode 600 for measuring a capacitance may be located in the upper heater 200 described above.

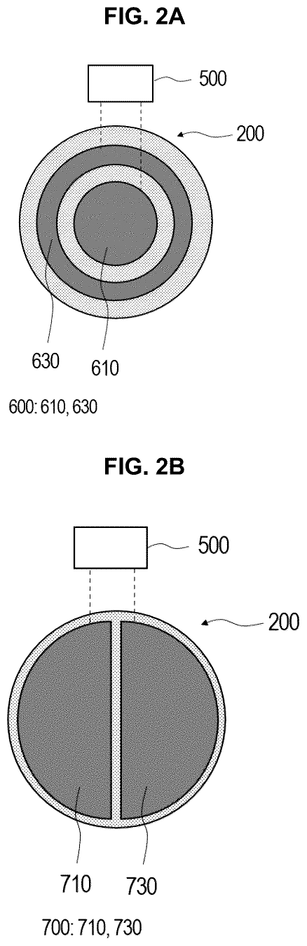

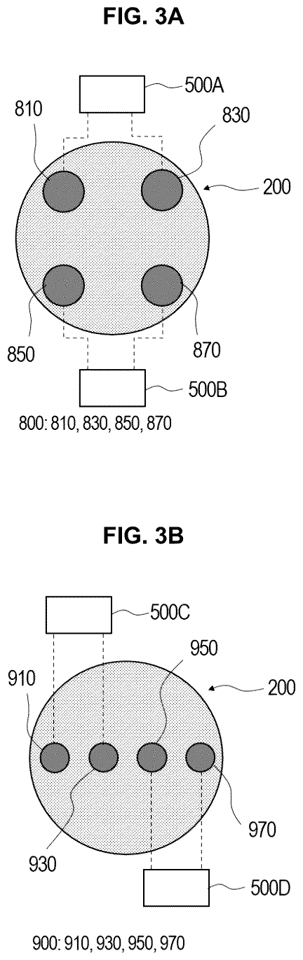

FIGS. 2A to 3B are plan views showing arrangement of the upper electrodes 600, 700, 800, and 900 according to various embodiments.

Referring to FIG. 1 and FIG. 2A, the upper electrode 600 may include a plurality of split electrodes 610 and 630.

For example, the upper electrode 600 may include a first split electrode 610 and a second split electrode 630 that are arranged in a circumferential direction centered on a central portion of the upper heater 200. In the present embodiment, two split electrodes are illustrated, but this is not limited thereto and three split electrodes or more may be provided.

The first split electrode 610 may be located at the central portion of the upper heater 200, and the second split electrode 630 may be located in a circumferential direction at a predetermined interval from the first split electrode 610.

The detector 500 that detects a capacitance may be connected to the first split electrode 610 and the second split electrode 630.

Accordingly, when measuring a capacitance between the first split electrode 610 and the second split electrode 630, the detector 500 may measure the capacitance between the first split electrode 610 and the substrate S and between the substrate S and the second split electrode 630 as shown in FIG. 1. That is, the capacitance between the upper electrode 600 and the substrate S may be measured by the detector 500.

In the arrangement as in FIG. 2A, it may be advantageous to detect a warpage degree of the entire substrate S, and in particular, it may be advantageous to detect a warpage degree in a radial direction of the substrate S.

The capacitance measured by the detector 500 may change depending on a progress of the process for the substrate S.

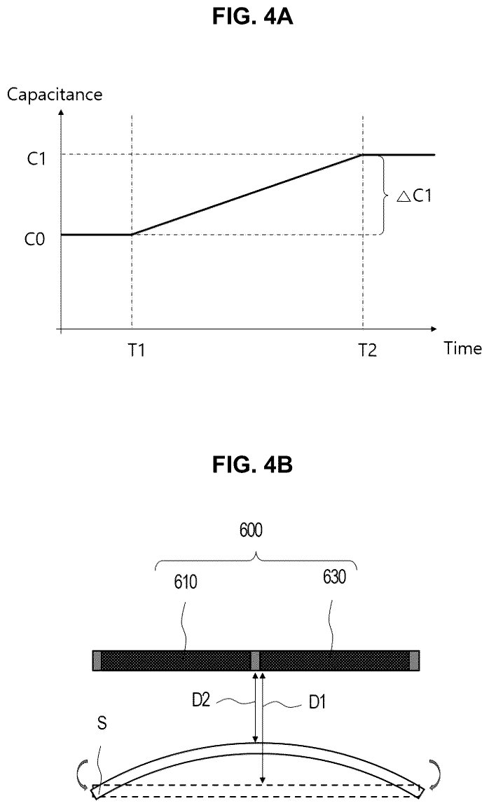

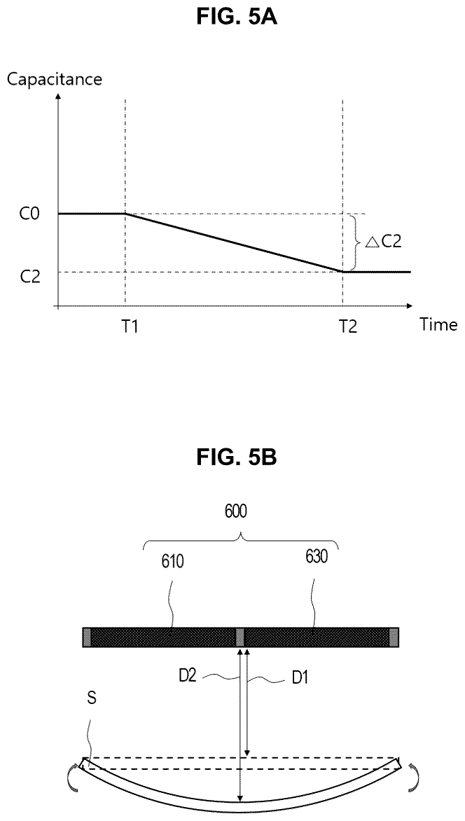

FIGS. 4A to 5B are graphs showing a change in a capacitance during a process for the substrate S and show warpage of the substrate S. In FIG. 4A and FIG. 5B, a horizontal axis shows a time ‘Time’ according to a process progress, and a vertical axis shows a capacitance measured by the detector 500. FIG. 4B and FIG. 5B illustrate a state in which compressive stress and tensile stress are applied to the substrate S. In FIG. 4B and FIG. 5B, the substrate S in a state of no warpage is indicated by a hidden line, and the substrate S after warpage is indicated by a solid line.

Referring to FIG. 4A, a process for the substrate S may begin (T1) and plasma may be provided while supplying process gas through the lower showerhead 430 described above to deposit a thin film on the backside of the substrate S.

In this case, when warpage occurs in the substrate S depending on a type of stress applied to the substrate S by the thin film, a distance between the substrate S and the upper electrode 600 may decrease or increase.

FIG. 4B shows a case in which a compressive stress is applied to the substrate S by the thin film deposited on the backside of the substrate S, and the distance between the substrate S and the upper electrode 600 is reduced from a first distance D1 to a second distance D2. As a gap between the upper electrode 600 and the substrate S decreases, the measured value of capacitance measured by the detector 500 increases.

That is, as shown in FIG. 4A, the measured value of the capacitance measured by the detector 500 increases approximately in proportion to a warpage degree of the substrate S.

Accordingly, when the amount of change ΔC1 in the measured value of the capacitance detected by the detector 500 is greater than or equal to a difference between an initial measured value C0 and a predetermined first threshold value C1, the process for the substrate S by the substrate processing apparatus 1000 may be terminated (T2) or the warpage degree of the substrate S may be notified through alarms or the like, or the warpage degree of the substrate S may be displayed through a display unit (not shown).

FIG. 5B shows a case in which a tensile stress is applied to the substrate S by the thin film deposited on the backside of the substrate S, and the distance between the substrate S and the upper electrode 600 increases from the first distance D1 to the second distance D2. As the gap between the upper electrode 600 and the substrate S increases, the measured value of capacitance measured by the detector 500 decreases.

That is, as shown in FIG. 4A, the measured value of the capacitance measured by the detector 500 decreases approximately in proportion to a warpage degree of the substrate S.

Accordingly, when the amount of change ΔC2 in the measured value of the capacitance detected by the detector 500 is greater than or equal to a difference between an initial measured value C0 and a predetermined second threshold value C2, the process for the substrate S by the substrate processing apparatus 1000 may be terminated (T2), or the warpage degree of the substrate S may be notified through alarms or the like, or the warpage degree of the substrate S may be displayed through a display unit (not shown).

Referring to FIG. 2B, the split electrodes 710 and 730 may be configured in a semicircular shape.

As shown in FIG. 2B, the upper electrode 700 may include a first split electrode 710 and a second split electrode 730 in a semicircular shape. In FIG. 2B, the first split electrode 710 and the second split electrode 730 are illustrated as having the same area, but this is not limited thereto and the first split electrode 710 and the second split electrode 730 may be arranged to have different areas.

In this case, the detector 500 may be connected to the first split electrode 710 and the second split electrode 730.

In the arrangement as in FIG. 2B, it may be advantageous to detect a warpage degree of the entire substrate S, and in particular, it may be advantageous to detect a warpage degree of a left side and a right side of the substrate S.

Referring to FIG. 3A, the upper electrode 800 may include, for example, a plurality of split electrodes 810, 830, 850, and 870.

The first split electrode 810, the second split electrode 830, the third split electrode 850, and the fourth split electrode 870 may be arranged along the upper heater 200. In FIG. 3A, the split electrodes 810, 830, 850, and 870 are illustrated as being arranged along the edge of the upper heater 200, but are not limited thereto and may also be arranged along the central portion of the upper heater 200.

When the number of the split electrodes 810, 830, 850, and 870 increases, the detector 500 may also be provided in plural. For example, a first detector 500A may be connected to the first split electrode 810 and the second split electrode 830, and a second detector 500B may be connected to the third split electrode 850 and the fourth split electrode 870.

Accordingly, in the case of the embodiments described above shown in FIGS. 2A and 2B, an area for measuring a capacitance between the upper electrodes 600 and 700 and the substrate S may not be specified, but in an embodiment in FIG. 3A, the area for measuring the capacitance may be appropriately adjusted by adjusting the number or/and arrangement of the plurality of split electrodes 810, 830, 850, and 870.

When a plurality of stresses are applied to the substrate S, the substrate S may warp into a so-called ‘saddle type’ in which the substrate S does not warp in one direction but in multiple directions. In the arrangement shown in FIG. 3A, the substrate S due to warpage of the saddle type described above may be detected more effectively.

In the present embodiment, the measurement values of capacitances measured by the first detector 500A and the second detector 500B may be compared with each other to compare warpage degrees according to the area of the substrate S. When the amount of change ΔC in the measured value of the capacitance detected by the first detector 500A and the second detector 500B is greater than or equal to a difference between an initial measured value and a predetermined threshold value, the process for the substrate S by the substrate processing apparatus 1000 may be terminated (T2), the warpage degree of the substrate S may be notified through alarms or the like, or the warpage degree of the substrate S may be displayed through a display unit (not shown).

Referring to FIG. 3B, the upper electrode 900 may include, for example, a plurality of split electrodes 910, 930, 950, and 970.

The first split electrode 910, the second split electrode 930, the third split electrode 950, and the fourth split electrode 970 may be arranged along an imaginary axis passing through a central portion of the upper heater 200. In FIG. 3B, the split electrodes 910, 930, 950, and 970 are illustrated as being arranged along a horizontal axis passing through the central axis of the upper heater 200, but are not limited thereto and may be arranged along a vertical axis or an inclined axis. Alternatively, the split electrodes 910, 930, 950, and 970 may be arranged along an imaginary line that does not pass through the central portion of the upper heater 200.

When the number of the split electrodes 910, 930, 950, and 970 increases, the detector 500 may also be provided in plural. For example, a third detector 500C may be connected to the first split electrode 910 and the second split electrode 930, and a fourth detector 500D may be connected to the third split electrode 950 and the fourth split electrode 970.

In the arrangement such as FIG. 3B, it may be advantageous to detect a warpage degree along one axis of the substrate S.

In the present embodiment, the measured values of the capacitances measured by the third detector 500C and the fourth detector 500D may be compared with each other to compare warpage degrees according to the area of the substrate S. When the amount of change ΔC in the measured value of the capacitance detected by the third detector 500C and the fourth detector 500D is greater than or equal to a difference between an initial measured value and a predetermined threshold value, the process for the substrate S by the substrate processing apparatus 1000 may be terminated (T2) or notified the warpage degree of the substrate S through alarms or the like, or the warpage degree of the substrate S may be displayed through a display unit (not shown).

According to the present disclosure having the configuration described above, a warpage degree of a substrate may be accurately detected by measuring a capacitance inside a chamber, for example, a capacitance between an upper electrode and the substrate inside the chamber.

Although the present disclosure has been described above with reference to embodiments thereof, those of skill in the art will appreciate that various modifications and changes may be made to the present disclosure without departing from the spirit and scope of the disclosure as set forth in the claims below. Therefore, if a modified implementation basically includes components of the claims of the present disclosure, it should be considered to be included in the scope of the present disclosure.

What is claimed is:

1. A substrate processing apparatus comprising:
a chamber providing a processing space for a substrate;
an upper electrode disposed at an upper portion inside the chamber;
a substrate support supporting the substrate inside the chamber;
a lower showerhead disposed inside the substrate support and providing process gas or plasma toward a backside of the substrate; and
a detector configured to measure a capacitance between the upper electrode and the substrate to detect a warpage degree of the substrate.

2. The substrate processing apparatus of claim 1, wherein the upper electrode includes a plurality of split electrodes, and
the detector is configured to measure a capacitance between the plurality of split electrodes and the substrate.

3. The substrate processing apparatus of claim 2, wherein, when an amount of change in the measured capacitance is greater than or equal to a difference between an initial measured value and a predetermined threshold value, a process for the substrate is terminated, the warpage degree of the substrate is notified through an alarm or the warpage degree of the substrate is displayed through a display unit.

4. The substrate processing apparatus of claim 2, wherein a number or arrangement of the plurality of split electrodes are changed to adjust an area in which a capacitance is measured by the detector.

5. The substrate processing apparatus of claim 2, wherein the detector includes a plurality of detectors, and
measured values of capacitances measured by the respective detectors are compared with each other to compare warpage degrees depending on an area of the substrate.

6. A substrate monitoring method of a substrate processing apparatus including an upper electrode disposed inside a chamber, a lower showerhead supplying process gas or plasma toward a backside of the substrate, and a detector measuring a capacitance between the upper electrode and the substrate, the substrate monitoring method comprising:
measuring a capacitance between the upper electrode and the substrate by the detector; and
determining a warpage degree of the substrate according to a measured value of the capacitance measured by the detector.

7. The substrate monitoring method of claim 6, wherein, when the upper electrode includes a plurality of split electrodes, the detector is configured to measure a capacitance between the plurality of split electrodes and the substrate.

8. The substrate monitoring method of claim 7, further comprising, when the detector includes a plurality of detectors, comparing measured values of capacitances measured by the respective detectors with each other to compare warpage degrees depending on an area of the substrate.

9. The substrate monitoring method of claim 6, further comprising, when an amount of change in the measured capacitance is greater than or equal to a difference between an initial measured value and a predetermined threshold value, terminating a process for the substrate, notifying the warpage degree of the substrate through an alarm or displaying the warpage degree of the substrate through a display unit.
